(19) United States
(12) Patent Application Publication
(10) Pub. No.: US 2014/0338741 A1
(43) Pub. Date: Nov. 20, 2014

(54) CONDUCTING SUBSTRATE FOR A PHOTOVOLTAIC CELL

(71) Applicant: SAINT-GOBAIN GLASS FRANCE, Courbevoie (FR)

(72) Inventors: Joerg Palm, Munich (DE); Mathieu Urien, Vincennes (FR); Gerard Ruitenberg, Herzogenrath (DE); Charles Leyder, Paris (FR); Andreas Heiss, Germering (DE); Erwan Mahe, Orvault (FR); Delphine Dupuy, Massy (FR)

(73) Assignee: SAINT-GOBAIN GLASS FRANCE, Courbevoie (FR)

(21) Appl. No.: 14/357,470

(22) PCT Filed: Nov. 9, 2012
(86) PCT No.: PCT/FR12/52586

§ 371 Date: May 9, 2014

(30) Foreign Application Priority Data
Nov. 9, 2011 (FR) 1160210

(51) Int. Cl. H01L 31/0224; H01L 31/18; H01L 31/0216; H01L 31/0296

(52) U.S. Cl. CPC H01L 31/022425; H01L 31/0296; H01L 31/1828; H01L 31/02167
USPC 136/256; 438/95

(57) ABSTRACT

A subject-matter of the invention is a conducting substrate (1) for a photovoltaic cell, comprising a carrier substrate (2) and an electrode coating (6) formed on the carrier substrate (2). The electrode coating (6) comprises a main molybdenum-based layer (8) formed on the carrier substrate (2), a barrier layer to selenization (10) formed on the main molybdenum-based layer (8) and, on the barrier layer to selenization (10), an upper layer (12) based on a metal M capable of forming, after sulfurization and/or selenization, an ohmic contact layer with a photoactive semiconducting material. The barrier layer to selenization (10) has a thickness of less than or equal to 50 nm, preferably of less than or equal to 30 nm, more preferably of less than or equal to 20 nm.

The invention relates to the field of photovoltaic cells, more particularly to the field of molybdenum-based conducting substrates used to manufacture thin-layer photovoltaic cells.

Specifically, in a known way, some thin-layer photovoltaic cells, referred to as second generation, use a molybdenum-based conducting substrate coated with a layer of absorbing agent (i.e., photoactive material), generally made of copper Cu, indium In, and selenium Se and/or sulfur S chalcopyrite. It can, for example, be a material of the CuInSe₂ type. This type of material is known under the abbreviation CIS. It can also be CIGS, that is to say a material additionally incorporating gallium, or also materials of the Cu₂(Zn,Sn)(S,Se)₄ (i.e., CZTS) type, using zinc and/or tin instead of indium and/or gallium.

For this type of application, the electrodes are generally based on molybdenum (Mo) as this material exhibits a number of advantages. It is a good electrical conductor (relatively low resistivity of the order of 10 μΩ.cm). It can be subjected to the necessary high heat treatments as it has a high melting point (2610° C.). It withstands, to a certain extent, selenium and sulfur. The deposition of the layer of absorbing agent generally requires contact with an atmosphere comprising selenium or sulfur, which tends to damage the majority of metals. Molybdenum reacts with selenium or sulfur, in particular, forming MoSe₂, MoS₂ or Mo(S,Se)₂, but keeps the bulk of its properties, in particular electrical properties, and retains an appropriate electrical contact with, for example, the CIS, CIGS, or CZTS layer. Finally, it is a material to which the layers of CIS, CIGS or CZTS type adhere well; the molybdenum even tends to promote the crystal growth thereof.

However, molybdenum exhibits a major disadvantage when industrial production is envisaged: it is an expensive material. This is because the molybdenum layers are normally deposited by cathode sputtering (magnetic-field-assisted). In point of fact, molybdenum targets are expensive. This is all the more important as, in order to obtain the desired level of electrical conductivity (a resistance per square of less than or equal to 2 Ω/□ and preferably of less than or equal to 1 or even 0.5 Ω/□, after treatment in an atmosphere containing S or Se), a relatively thick layer of Mo, generally of the order of from 400 nm to 1 micrometer, is necessary.

Patent Application WO-A-02/065554 from Saint-Gobain Glass France teaches the provision of a relatively thin layer of molybdenum (less than 500 nm) and the provision of one or more layers impermeable to alkali metals between the substrate and the molybdenum-based layer, so as to retain the qualities of the thin molybdenum-based layer during the subsequent heat treatments.

Nevertheless, this type of conducting substrate remains relatively expensive.

One aim of the present invention is to provide a novel molybdenum-based conducting substrate, the manufacturing cost of which is relatively low.

To this end, a subject-matter of the present invention is in particular a conducting substrate for a photovoltaic cell, comprising a carrier substrate and an electrode coating formed on the carrier substrate, in which the electrode coating comprises:
a main molybdenum-based layer formed on the carrier substrate;
a barrier layer to selenization formed on the main molybdenum-based layer, the barrier layer to selenization having a thickness of less than or equal to 50 nm, preferably of less than or equal to 30 nm, more preferably of less than or equal to 20 nm; and
on the barrier layer to selenization, an upper layer based on a metal M capable of forming, after sulfurization and/or selenization, an ohmic contact layer with a photoactive semiconducting material.

Such a conducting substrate exhibits the advantage of making it possible to obtain, with reduced molybdenum thicknesses, a resistance per square equivalent to that of a conducting substrate, the electrode coating of which is composed of just one molybdenum layer.

By virtue of the conducting substrate, the process for the manufacture of the photovoltaic cell (or photovoltaic module) is in addition particularly reliable. This is because the barrier layer to selenization makes it possible both to guarantee the presence and the amount of Mo(S,Se)₂ by the transformation of the whole of the upper layer (for example if its thickness is between 10 and 50 nm), while guaranteeing the presence and a uniform thickness of a main molybdenum-based layer, the conductance properties of which have been retained. The retention of the qualities of the main molybdenum-based layer and the uniformity of the thickness thereof make it possible to reduce the amounts of materials to the minimum.

The uniformity of the ohmic contact layer formed by the upper layer after selenization and/or sulfurization is additionally beneficial to the efficiency of the solar cell.

WO-A-2005/088731 describes an improvement in the coefficient of reflection of the conducting substrate with a layer of TiN or ZrN. Nevertheless, the absorbing layers tested for the present invention were too thick for this effect to be able to influence the performance. What is more, the layers of TiON tested here were also too thin to significantly increase the coefficient of reflection.

According to specific embodiments, the conducting substrate comprises one or more of the following characteristics, taken in isolation or according to all the combinations technically possible:

the barrier layer to selenization is based on a metal nitride or oxynitride with the metal M chosen from titanium, molybdenum, zirconium or tantalum and an oxygen content x=O/(O+N) with x=0 or 0<x<1;

the barrier layer to selenization is based on a metal oxynitride with the metal M chosen from titanium, molybdenum, zirconium or tantalum and an oxygen content x=O/(O+N) with 0<x<1, for example 0.05<x<0.95, for example 0.1<x<0.9;

the barrier layer to selenization has a resistivity of between 200 μohm.cm and 500 μohm.cm;

the barrier layer to selenization is a molybdenum-based compound with a high content of oxygen and/or nitrogen;

the barrier layer to selenization has a resistivity of between 20 μohm.cm and 50 μohm.cm;

the said metal M is capable of forming a compound of semiconducting sulfide and/or selenide type of p type with a concentration of charge carriers of greater than or equal to 10¹⁶/cm³ and a work function of greater than or equal to 4.5 eV;

the said upper layer based on a metal M is molybdenum-based and/or tungsten-based;

the said upper layer based on a metal M has a thickness of greater than or equal to 10 nm, preferably of greater than or equal to 20 nm, and of less than or equal to 100 nm, preferably of less than or equal to 50 nm;

the barrier layer to selenization has a thickness of greater than or equal to 3 nm, preferably of greater than or equal to 5 nm;

the main molybdenum-based layer has a thickness of less than or equal to 400 nm, for example of less than or equal to 300 nm, for example of less than or equal to 250 nm;

the main molybdenum-based layer has a thickness of greater than or equal to 40 nm, preferably of greater than or equal to 150 nm;

the main molybdenum-based layer has a uniform thickness, the thickness preferably remaining within a range of +/−10% with respect to a mean value;

the electrode coating has a resistance per square of less than or equal to 2 Ω/□, preferably of less than or equal to 1 Ω/□;

the said upper layer based on a metal M is formed directly on the barrier layer to selenization;

the barrier layer to selenization is formed directly on the main molybdenum-based layer;

the carrier substrate is made of a material comprising alkali metals, the conducting substrate comprising one or more barrier layers to alkali metals formed on the carrier substrate and under the main molybdenum-based layer, the barrier layer or layers to alkali metals being, for example, based on one of the materials chosen from: silicon nitride, silicon oxide, silicon oxynitride, silicon oxycarbide, aluminum oxide or aluminum oxynitride;

the carrier substrate is a glass sheet.

Another subject-matter of the invention is a semiconducting device comprising a carrier substrate and an electrode coating formed on the carrier substrate, the electrode coating comprising:

a main molybdenum-based layer;

a barrier layer to selenization formed on the main molybdenum-based layer;

a photoactive layer made of a photoactive semiconducting material based on copper and selenium and/or sulfur chalcopyrite, for example a material of Cu(In,Ga)(S,Se)₂ type, in particular CIS or CIGS, or also a material of Cu₂(Zn,Sn)(S,Se)₄ type, the photoactive layer being formed on the barrier layer to selenization; and

between the barrier layer to selenization and the photoactive layer, an ohmic contact layer based on a compound of the type consisting of sulfide and/or selenide of a metal M.

According to specific embodiments, the semiconducting device comprises one or more of the following characteristics, taken in isolation or according to all the combinations technically possible:

the material of the ohmic contact layer is a semiconducting material of p type with a concentration of charge carriers of greater than or equal to 10¹⁶/cm³ and a work function of greater than or equal to 4.5 eV;

the ohmic contact layer is based on a compound of molybdenum and/or tungsten sulfide and/or selenide type.

Another subject-matter of the invention is a photovoltaic cell comprising a semiconducting device as described above and a transparent electrode coating formed on the photoactive layer.

Another subject-matter of the invention is a photovoltaic module comprising a plurality of photovoltaic cells connected to one another in series and all formed on the same substrate, in which the photovoltaic cells are as described above.

Another subject-matter of the invention is a process for the manufacture of a conducting substrate for a photovoltaic cell, comprising stages consisting in:

depositing a main molybdenum-based layer on a carrier substrate;

depositing a barrier layer to selenization on the main molybdenum-based layer;

depositing, on the barrier layer to selenization, an upper layer based on a metal M capable of forming, after sulfurization and/or selenization, an ohmic contact layer with a photoactive semiconducting material; and

transforming the upper layer based on a metal M into a sulfide and/or selenide of the metal M.

According to specific embodiments, the process exhibits one or more of the following characteristics, taken in isolation or according to all the combinations technically possible:

the process comprises a stage of formation of a photoactive layer, by selenization and/or sulfurization, on the said upper layer based on a metal M, the stage of transformation of the said upper layer based on a metal M being carried out before or during the formation of the said photoactive layer, preferably during;

after sulfurization and/or selenization, the said upper layer is based on a semiconductor of p type with a concentration of charge carriers of greater than or equal to 10¹⁶/cm³ and a work function of greater than or equal to 4.5 eV;

after sulfurization and/or selenization, the said upper layer is a compound based on molybdenum and/or tungsten sulfide and/or selenide;

the stage of formation of the photoactive layer comprises a stage of selenization and/or sulfurization at a temperature of greater than or equal to 300° C.

A better understanding of the invention will be obtained on reading the description which will follow, given solely by way of example and made with reference to the appended drawings, in which:

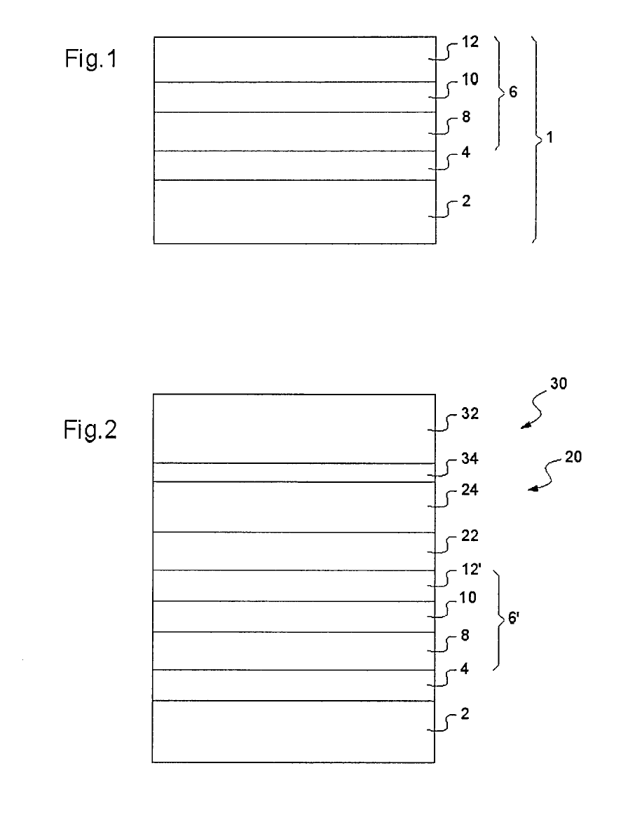

FIG. 1 is a diagrammatic view in cross section of a conducting substrate;

FIG. 2 is a diagrammatic view in cross section of a photovoltaic cell comprising a conducting substrate according to FIG. 1;

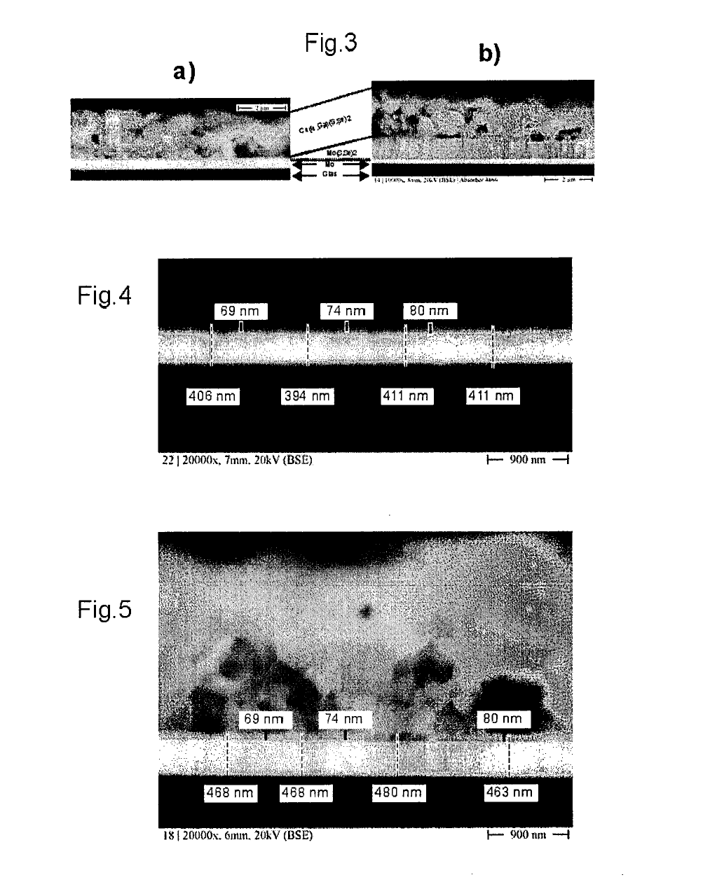

FIGS. 3a and 3b are views in cross section obtained by electron microscopy, FIG. 3b representing a semiconducting device after treatment at high temperature and high selenium partial pressure, the conducting substrate of which originally only had just one molybdenum layer, whereas it additionally had, in FIG. 3a, a barrier layer to selenization, based on TiON, and an upper ohmic contact layer, based on Mo;

FIG. 4 is an image in cross section by electron microscopy of the section of an improved conducting substrate;

FIG. 5 is an analogous image to that of FIG. 4 of a semiconducting device in which a thin CIGSSe layer has been formed by selenization on the conducting substrate of FIG. 4;

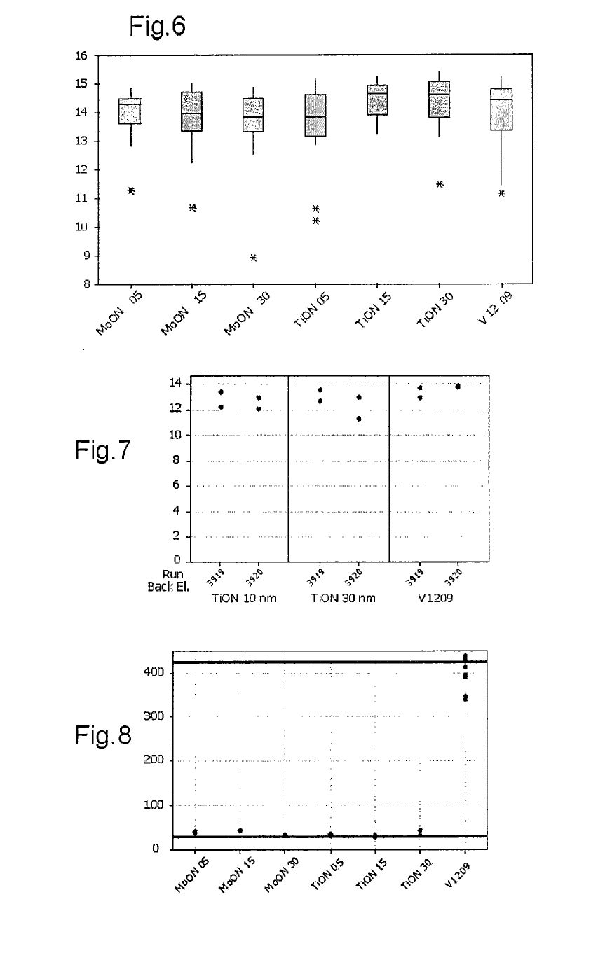

FIGS. 6 and 7 illustrate the effectiveness of cells using Si₃N₄ (140 nm)/Mo conducting substrates with different thicknesses of Mo, with and without a barrier layer to selenization; and

FIG. 8 shows experimental results of selenization tests as described below.

The drawings in FIGS. 1 and 2 are not to scale, for a clear representation, as the differences in thickness between in particular the carrier substrate and the layers deposited are significant, for example of the order of a factor of 500.

FIG. 1 illustrates a conducting substrate 1 for a photovoltaic cell comprising:

a carrier substrate 2 made of glass;

a barrier layer to alkali metals 4 formed on the substrate 2; and

a molybdenum-based electrode coating 6 formed on the barrier layer to alkali metals 4.

Throughout the text, the expression “a layer A formed (or deposited) on a layer B” is understood to mean a layer A formed either directly on the layer B and thus in contact with the layer B or formed on the layer B with interposition of one or more layers between the layer A and the layer B.

It should be noted that, throughout the text, the term “electrode coating” is understood to mean a current-supplying coating comprising at least one layer which conducts electrons, that is to say having a conductivity which is provided by the mobility of electrons.

In addition, throughout the text, the expression “comprises a layer” should, of course, be understood as “comprises at least one layer”.

The electrode coating 6 illustrated is composed:

of a main molybdenum-based layer 8 formed directly on the barrier layer to alkali metals 4;

of a barrier layer to selenization 10 formed directly on the main molybdenum-based layer 8 and which is thin; and

of an upper layer 12 based on a metal M formed directly on the barrier layer to selenization 10.

Such a conducting substrate 1 is intended for the manufacture of a photoactive material with addition of sodium (it is known that sodium improves the performances of photoactive materials of CIS or CIGS type). The barrier layer to alkali metals 4 prevents the migration of the sodium ions from the substrate 2 made of glass, for better control of the addition of sodium to the photoactive material.

In the case where the substrate does not comprise alkali metal ions, the barrier layer to alkali metals 4 can be omitted.

Another technique for the manufacture of the photoactive material consists in using the migration of the sodium ions from the carrier substrate made of glass in order to form the photoactive material. In this case, the conducting substrate 1 does not have a barrier layer to alkali metals 4 and the main layer 8 of molybdenum is, for example, formed directly on the carrier substrate 2.

In an alternative form also, the electrode coating 6 comprises one or more inserted layers.

Thus, generally, the conducting substrate 1 comprises a carrier substrate 2 and an electrode coating 6 comprising:

a main molybdenum-based layer 8 formed on the carrier substrate 2;

a barrier layer to selenization 10 formed on the main molybdenum-based layer 8; and

an upper layer 12 based on a metal M formed on the barrier layer to selenization 10.

The metal M is capable of forming, after sulfurization and/or selenization, an ohmic contact layer with a photoactive semiconducting material, in particular with a photoactive semiconducting material based on copper and selenium and/or sulfur chalcopyrite, for example a photoactive material of Cu(In,Ga)(S,Se)₂ type, in particular CIS or CIGS, or also a material of Cu₂(Zn,Sn)(S,Se)₄ type.

The term “an ohmic contact layer” is understood to mean a layer of a material such that the current/voltage characteristic of the contact is non-rectifying and linear.

Preferably, the upper layer 12 is the final upper layer of the electrode coating 6, that is to say that the electrode coating 6 does not have another layer above the layer 12.

Preferably again, the electrode coating 6 comprises just one main molybdenum-based layer 8, just one barrier layer to selenization 10 and just one layer 12.

It should be noted that, throughout the text, the term “just one layer” is understood to mean a layer of one and the same material. This single layer can nevertheless be obtained by the superposition of several layers of one and the same material, between which exists an interface which it is possible to characterize, as described in WO-A-2009/080931.

Typically, in a magnetron deposition chamber, several layers of one and the same material will be successively formed on the carrier substrate by several targets in order to form, in the end, just one layer of one and the same material, namely molybdenum.

It should be noted that the term “molybdenum-based” is understood to mean a material composed of a substantial amount of molybdenum, that is to say either a material composed solely of molybdenum, or an alloy predominantly comprising molybdenum, or a compound predominantly comprising molybdenum but with a content of oxygen and/or nitrogen, for example a content resulting in a resistivity of greater than or equal to 20 μohm.cm.

The layer 12 is intended to be fully transformed, by selenization and/or sulfurization, into Mo(S,Se)₂, which material is not, on the other hand, regarded as a “molybdenum-based” material but a material based on molybdenum disulfide, on molybdenum diselenide or on a mixture of molybdenum disulfide and diselenide.

Conventionally, the notation (S,Se) indicates that this concerns a combination of SₓSe₁₋ₓ with 0≦x≦1.

It should be noted that the substrate illustrated in FIG. 1 and described above is an intermediate product in the manufacture of a photovoltaic module. This intermediate product is subsequently transformed as a result of the process for the manufacture of the photoactive material. The conducting substrate 1 described above is understood as the intermediate product before transformation, which can be stored and despatched to other production sites for the manufacture of the module.

The upper layer 12, so as to act as ohmic contact once transformed into Mo(S,Se)₂, for example has a thickness of greater than or equal to 10 nm and less than or equal to 100 nm, preferably of between 30 nm and 50 nm. A great thickness is not necessary.

The said metal M is advantageously molybdenum-based and/or tungsten-based.

The molybdenum disulfide and/or diselenide compounds Mo(S,Se)₂ are materials having a proven effectiveness as ohmic contact layer. Tungsten (W) is a material with similar chemical properties. It also forms chalcogenide semiconductors WS₂ and WSe₂. Mo(S,Se)₂ and W(S,Se)₂ can both be formed as semiconductors of p type with a doping agent of p type of greater than or equal to 10¹⁶/cm³ and a work function of approximately 5 eV. Generally, it can concern a material based on a metal M capable of forming a compound of semiconducting sulfide and/or selenide type of p type with a concentration of charge carriers of greater than or equal to 10¹⁶/cm³ and a work function of greater than or equal to 4.5 eV. More generally still, it concerns a metal M of any type capable of forming, after sulfurization and/or selenization, an ohmic contact layer with a photoactive semiconducting material, more particularly with a photoactive material based on copper and selenium and/or sulfur chalcopyrite.

The barrier layer to selenization 10 protects the main molybdenum-based layer 8 from possible selenization and/or sulfurization. It should be noted that a layer which protects from selenization also protects from sulfurization.

The term “barrier layer to selenization” is understood to mean a layer of a material of any type capable of preventing or reducing the selenization of layers covered with the barrier layer to selenization during the deposition, on the barrier layer to selenization, of layers of semiconducting materials formed by selenization and/or sulfurization. The barrier layer to selenization within the meaning of the invention shows a proven effectiveness even at a thickness of 3 nm.

A possible test for determining if a material is suitable or not for a role as barrier to selenization is to compare a sample with and without a layer of 5 nm of this material between the upper layer 12 based on a metal M and the main layer 8 and to subject the samples to a selenization, for example by heating at 520° C. in a 100% selenium atmosphere. If the selenization of the main layer 8 is reduced or prevented and the upper layer 12 is entirely selenized, the material is effective.

The material of the barrier layer to selenization 10 is, for example, based on a metal nitride, such as titanium nitride, molybdenum nitride, zirconium nitride or tantalum nitride, or a combination of these materials. It may also concern an oxynitride.

Generally, it concerns a material of any type suitable for protecting the main molybdenum-based layer 8 from a possible selenization or sulfurization.

The material can also be based on a metal oxide, such as molybdenum oxide, titanium oxide or a mixed oxide of molybdenum and titanium.

However, the nitrides are preferred to the oxides.

More preferably, it concerns a material based on a metal oxynitride with M chosen from titanium, molybdenum, zirconium or tantalum and with a content of oxygen x=O/(O+N) with 0<x<1, for example 0.05<x<0.95, for example 0.1<x<0.9.

It should be noted that the above nitrides, oxides and oxynitrides can be substoichiometric, stoichiometric or superstoichiometric respectively in nitrogen and oxygen.

In an alternative form, it concerns a molybdenum-based layer, more specifically a molybdenum-based compound with a high content of oxygen and/or nitrogen. The content of oxygen and/or nitrogen is, for example, sufficient if it brings about a resistivity of greater than or equal to 20 μohm.cm.

Generally, it thus concerns a molybdenum-based layer with a high content of oxygen and/or nitrogen or concerns a material based on a metal nitride, oxide or oxynitride suitable for protecting the main molybdenum-based layer 8 from a possible selenization or sulfurization.

The barrier layer to selenization 10 is low in thickness. It has a thickness of less than or equal to 50 nm, preferably of less than or equal to 30 nm, more preferably of less than or equal to 15 nm.

If the barrier layer to selenization 10 is very thin, there is a risk of it no longer having a significant effect. It thus has, for example, a thickness of greater than or equal to 3 nm, preferably of greater than or equal to 5 nm. This is because, surprisingly, it turned out that a barrier layer to selenization 10 having so slight a thickness had a significant effect.

The barrier layer to selenization 10 has a lower conductivity than the main molybdenum-based layer 8. For example, it has a resistivity of between 200 μohm.cm and 500 μohm.cm, in the case of a layer based on a metal oxide, nitride or oxynitride, and a resistivity of between 20 μohm.cm and 50 μohm.cm in the case of a molybdenum-based material with a high content of nitrogen and/or oxygen.

As a result of the slight thickness of the barrier layer to selenization 10, a high resistivity is not harmful to the performance of the cell, the electrical current passing transversely.

The barrier layer to selenization 10 is, in addition, preferably capable of limiting the backward diffusion of the sodium ions towards the carrier substrate 2, that is to say the diffusion of the sodium ions from the top of the upper layer 12 through the upper layer 12 and towards the carrier substrate 2.

This property is advantageous in several respects.

It renders more reliable the manufacturing processes consisting in adding alkali metals in order to form the photoactive material, for example by deposition of sodium diselenide on the upper layer 12 of the electrode coating 6 or by addition of sodium during the deposition of the photoactive material, for example using targets comprising sodium or other alkali metals, as described in U.S. Pat. No. 5,626,688.

The main molybdenum-based layer 8 has a sufficient thickness for the electrode coating 6 to have, after a selenization test as described above, a resistance per square of less than or equal to 2 Ω/□, preferably of less than or equal to 1 Ω/□. The presence of the upper layer 12 based on the metal M and of the barrier layer to selenization 10 makes it possible to achieve such performances.

Assuming an electrode coating 6 not comprising other electrically conducting layers than the main molybdenum-based layer 8, the barrier layer to selenization 10 and the upper layer 12 based on the metal M, the main molybdenum-based layer 8, in order to have a significant effect, preferably has a thickness of greater than or equal to 40 nm, preferably of greater than or equal to 150 nm. However, the main molybdenum-based layer 8 has, for example, a thickness of less than or equal to 400 nm, for example of less than or equal to 300 nm, for example of less than or equal to 250 nm.

There is an advantage to reducing the thickness of the main molybdenum-based layer 8: to make it possible to deposit this relatively thin layer by cathode sputtering with deposition parameters resulting in a highly constrained layer, without the problems of delamination which may be encountered with thick layers.

The main molybdenum-based layer 8 is, for example, composed of molybdenum, that is to say that it comprises only molybdenum.

The carrier substrate 2 and the barrier layer to alkali metals 4 will now be described.

Two cases are to be distinguished: the case where a migration of alkali metal ions from the substrate is desired in order to dope the layer of photoactive material and the case where this migration is not desired.

The substrates provided with one or more barrier layers to alkali metals 4 are used in the second case, in particular in order to make it possible to use, as substrate, a sheet of glass of soda-lime-silica type obtained by the float process, glass of relatively low cost which exhibits all the qualities which are known in this type of material, such as, for example, its transparency, its impermeability to water and its hardness.

The content of alkali metal ions of the substrate 2 is, in this case, a disadvantage which the barrier layer to alkali metals will minimize.

The barrier layer to alkali metals 4 is, for example, based on one of the materials chosen from: silicon nitride, silicon oxide, silicon oxynitride, silicon oxycarbide, aluminum oxide or aluminum oxynitride.

In an alternative form, still in the second case, the carrier substrate 2 is a sheet of a material of any appropriate type, for example a silica-based glass not comprising alkali metals, such as borosilicate glasses, or made of plastic, or even of metal.

In the first case, the carrier substrate 2 is of any appropriate type and comprises alkali metals, for example sodium ions and potassium ions. The substrate is, for example, a soda-lime-silica glass. The barrier layer to alkali metals is absent.

In both cases, the carrier substrate 2 is intended to act as back contact in the photovoltaic module and does not have to be transparent.

The sheet constituting the carrier substrate 2 can be flat or rounded, and can exhibit dimensions of any type, in particular at least one dimension of greater than 1 meter.

Another subject-matter of the invention is a process for the manufacture of the conducting substrate 1 described above.

The process comprises the stages consisting in:

depositing the main molybdenum-based layer 8 on the carrier substrate 2, with optional prior deposition of the barrier layer to alkali metals 4;

depositing the barrier layer to selenization 10 on the main molybdenum-based layer 8, for example directly on it;

depositing the upper layer 12 based on the metal M on the barrier layer to selenization 10; and

transforming the said layer based on metal M into a sulfide and/or selenide of the metal M. This transformation stage can be a separate stage before the formation of the CIS, CGS or CZTS semiconducting layer or a stage carried out during the selenization and/or sulfurization of the CIS, CGS or CZTS semiconducting layer, whether this selenization and/or sulfurization is carried out during the deposition of the said semiconducting layer or after deposition of metal components said to be precursors of the semiconducting layer.

The deposition of the various layers is, for example, carried out by magnetron cathode sputtering but, in an alternative form, another process of any appropriate type is concerned.

Another subject-matter of the invention is a semiconductor device 20 (FIG. 2) which uses the conducting substrate 1 described above to form one or more photoactive layers 22, 24 thereon.

The first photoactive layer 22 is typically a doped layer of p type, for example based on copper Cu, indium In, and selenium Se and/or sulfur S chalcopyrite. It can be, for example, as explained above, CIS, CIGS or CZTS.

The second photoactive layer 24 is doped, of n type and described as buffer. It is, for example, composed of CdS (cadium sulfide) and is formed directly on the first photoactive layer 22.

In an alternative form, the buffer layer 24 is, for example, based on InₓS_{y}, Zn(O,S) or ZnMgO or is made of another material of any appropriate type. In an alternative form again, the cell does not comprise a buffer layer, it being possible for the first photoactive layer 22 to itself form a p-n homojunction.

Generally, the first photoactive layer 22 is a layer of p type or having a p-n homojunction obtained by addition of alkali metal elements.

The deposition of the photoactive layer comprises stages of selenization and/or sulfurization, as explained in more detail below. The deposition can be carried out by evaporation of the elements Cu, In, Ga and Se (or Cu, Sn, Zn, S). During these selenization and/or sulfurization stages, the upper layer 12 based on the metal M is transformed into a layer 12′ based on M(S,Se)₂. This transformation concerns, for example, the whole of the upper layer 12.

The semiconducting device 20 thus comprises:

the carrier substrate 2 and the electrode coating 6′ formed on the carrier substrate 2, the upper layer 12′ of which has been transformed.

The electrode coating 6′ comprises:

the main molybdenum-based layer 8;

the barrier layer to selenization 10 formed on the main molybdenum-based layer 8; and

the upper ohmic contact layer 12′, based on M(S,Se)₂, formed on the barrier layer to selenization 10. The semiconducting device comprises, on the ohmic contact layer 12′ and in contact with the latter, the photoactive semiconducting layer or layers 14, 16.

Another subject-matter of the invention is a photovoltaic cell 30 comprising a semiconducting device 20 as described above.

The cell comprises, for example, as illustrated in FIG. 2:

the semiconducting device 20 formed by the layers 8, 10, 12′, 22 and 24;

a transparent electrode coating 32, for example made of ZnO:Al, formed on the first photoactive layer 22 and on the buffer layer 24, in the event of the presence of the latter, with optional interposition, between the transparent electrode coating 32 and the semiconducting device 20, of a passivating layer 34, for example of intrinsic ZnO or of intrinsic ZnMgO.

The transparent electrode coating 32 comprises, in an alternative form, a layer of zinc oxide doped with gallium, or boron, or also an ITO layer.

Generally, it is a transparent conducting material (TCO) of any appropriate type.

For a good electrical connection and good conductance, a metal grid (not represented in FIG. 2) is subsequently optionally deposited on the transparent electrode coating 32, for example through a mask, for example by an electron beam. It is, for example, an Al (aluminum) grid, for example with a thickness of approximately 2 μm, on which is deposited an Ni (nickel) grid, for example with a thickness of approximately 50 nm, in order to protect the Al layer.

The cell 30 is subsequently protected from external attacks. It comprises, for example, to this end, a counter-substrate (not represented) covering the front electrode coating 32 and laminated to the carrier substrate 2 via a lamination interlayer (not represented) made of thermoplastic. It is, for example, a sheet of EVA, PU or PVB.

Another subject-matter of the invention is a photovoltaic module comprising several photovoltaic cells formed on the same substrate 2, which cells are connected to one another in series and are obtained by margination of the layers of the semiconducting device 20.

Another subject-matter of the invention is a process for the manufacture of the semiconducting device 20 and of the photovoltaic cell 30 above, which process comprises a stage of formation of a photoactive layer by selenization and/or sulfurization.

Numerous known processes exist for the manufacture of a photoactive layer of Cu(In,Ga)(S,Se)₂ type. The photoactive layer 22 is, for example, a CIGS layer formed in the following way.

In a first stage, the precursors of the layer are deposited on the electrode coating 6.

A metal stack composed of an alternation of layers of CuGa and In type is, for example, deposited on the electrode coating 6 by magnetron cathode sputtering at ambient temperature. A layer of selenium is subsequently deposited at ambient temperature directly on the metal stack, for example by thermal evaporation.

In an alternative form, the metal stack has, for example, a multilayer structure of Cu/In/Ga/Cu/In/Ga . . . type.

In a second stage, the substrate is subjected to a heating treatment at high temperature, referred to as RTP (“Rapid Thermal Process”), for example at approximately 520° C., in an atmosphere composed, for example, of gaseous sulfur, for example based on S or H₂S, thus forming a layer of CuInₓGa₁₋ₓ(S,Se)₂.

One advantage of this process is that it does not require an external source of selenium vapor. The loss of a portion of the selenium during the heating is compensated for by an excess deposition of selenium on the metal stack. The selenium necessary for the selenization is provided by the deposited layer of selenium.

In an alternative form, the selenization is obtained without the deposition of a layer of selenium but by an atmosphere comprising gaseous selenium, for example based on Se or H₂Se, prior to the exposure to an atmosphere rich in sulfur.

The sulfurization stage makes it possible to optionally do without a buffer layer, for example of CdS.

As explained above, it can be advantageous to deposit a layer based on alkali metals, for example on sodium, for exact metering of the sodium in the photoactive layer.

Prior to the deposition of the CuGa and In metal stack, the alkali metals are, for example, introduced by the deposition, on the sacrificial molybdenum-based layer 12, of a layer of sodium selenide or of a compound comprising sodium, so as to introduce, for example, of the order of 2×10¹⁵ sodium atoms per cm². The metal stack is deposited directly on this layer of sodium selenide.

It should be noted that there exist numerous possible alternative forms for forming the CI(G)S or CZTS layers, which alternative forms include, for example, the coevaporation of the abovementioned elements, chemical vapor deposition, electrochemical deposition of metals, selenides or chalcopyrites, reactive sputtering of metals or selenides in the presence of H₂Se or H₂S.

Generally, the process for the manufacture of the photoactive layer 22 is of any appropriate type.

All the processes for the manufacture of layers of CIS or CZTS type use a stage of heating at high temperature in the presence of selenium and/or of sulfur in the vapor state or in the liquid state.

### EXAMPLES AND RESULTS

The performances of photovoltaic cells incorporating different molybdenum-based electrode coatings have been successfully tested.

In all the examples, a carrier substrate 2 made of soda-lime-silica glass with a thickness of 3mm was used, with a barrier layer to alkali metals composed of Si₃N₄ and with a thickness of 140 nm deposited directly on the carrier substrate 2 made of glass.

The photovoltaic cells were produced by formation of Cu(In,Ga)(S,Se)₂ in two stages. A precursor stack comprising Cu, Ga, In and Na was deposited by a magnetron sputtering in the way described above.

A layer of selenium was subsequently deposited by thermal evaporation.

The precursor stack was subsequently transformed into Cu(In,Ga)(S,Se)₂ by the rapid thermal process RTP in an atmosphere comprising sulfur.

A layer 24 of CdS was subsequently deposited, followed by a layer 32 of ZnO:Al. Photovoltaic cells with an opening surface area of 1.4 cm² were produced by the deposition of a grid on the ZnO:Al layer. Modules with dimensions of 30×30 cm were manufactured by monolithic interconnection.

FIGS. 3a and 3b illustrate the effect of the barrier layer to selenization. FIG. 3b: due to a high temperature and a high selenium partial pressure, the thickness of the Mo(S,Se)₂ compound formed is several hundred nanometers, leaving only a very thin thickness of metallic Mo. FIG. 3a: the barrier layer to selenization prevents the selenization of the molybdenum layer, which it protects.

In the same way, FIG. 4 is an electron microscopy image showing a glass substrate of 3mm, a barrier layer to alkali metals based on silicon nitride of 130 nm, a layer of titanium nitride of 30 nm and a layer of molybdenum of 25 nm, before treatment. For its part, FIG. 5 shows the same substrate as in FIG. 4, after deposition of the photoactive layer and selenization. The total thickness of the back electrode, including the Mo(S,Se)₂ layer and the barrier layer to selenization, varies between 460 nm and 480 nm, the thickness of the Mo(S,Se)₂ layer for its part varying between 70 nm and 80 nm.

FIGS. 6 and 7 illustrate the energy conversion coefficient obtained as a function of the various conducting substrates used.

FIG. 6 exhibits experimental results obtained for photovoltaic cells which differ from one another in the thickness of the barrier layer to selenization, made of TiON or MoON (Examples 1 to 6), and compares these results with a photovoltaic cell with a conducting substrate without a barrier layer to selenization and a thick molybdenum layer (Example 7).

The output of the cell is on the ordinates in %.

The examples differ only in the molybdenum-based back electrode coating 6.

### Example 1

### MoON 05

glass (3mm)/Si₃N₄ (140 nm)/Mo (200 nm)/MoON (5 nm)/Mo (30 nm),

### Example 2

### MoON 15

glass (3mm)/Si₃N₄ (140 nm)/Mo (200 nm)/MoON (15 nm)/Mo (30 nm),

### Example 3

### MoON 30

glass (3mm)/Si₃N₄ (140 nm)/Mo (200 nm)/MoON (30 nm)/Mo (30 nm),

### Example 4

### TiON 05

glass (3mm)/Si₃N₄ (140 nm)/Mo (200 nm)/TiON (5 nm)/Mo (30 nm),

### Example 5

### TiON 15

glass (3mm)/Si₃N₄ (140 nm)/Mo (200 nm)/TiON (15 nm)/Mo (30 nm),

### Example 6

### TiON 30

glass (3mm)/Si₃N₄ (140 nm)/Mo (200 nm)/TiON (30 nm)/Mo (30 nm),

### Example 7

### V1209

glass (3mm)/Si₃N₄ (140 nm)/Mo (425 nm)

Examples 1 to 6 show an advantage in using a barrier layer based on TiON rather than a barrier layer based on MoON.

It should be noted that TiON or MoON is understood to mean an oxynitride with 0<x<1, x=O/(O+N), O and N being, of course, the atomic proportions.

Better results were obtained with a thickness of 5 nm in the case of MoON.

In the case of the TiON, the optimum thickness is approximately 15 nm.

The comparison of the results of Examples 1 to 6 with Example 7 shows in addition that it is possible to obtain equivalent performances with electrode coatings combining only 230 nm of Mo, i.e. 195 nm less than in Example 7, i.e. a substantial saving in material.

FIG. 7 illustrates the same type of results as FIG. 4 (i.e., energy output as %) but for complete modules composed of forty cells each and using standard glass/Si₃N₄ (140 nm)/Mo conducting substrates with different thicknesses of Mo:

### Example 8

### TiON10

glass (3mm)/Si₃N₄ (140 nm)/Mo (350 nm)/TiON (10 nm)/Mo (30 nm),

### Example 9

### TiON30

glass (3mm)/Si₃N₄ (140 nm)/Mo (350 nm)/TiON (30 nm)/Mo (30 nm),

### Example 10

### V1209

glass (3mm)/Si₃N₄ (140 nm)/Mo (425 nm).

Two rounds of experiments were carried out (3919 and 3920).

A greater thickness of molybdenum was chosen due to the margination carried out in order to define the different cells. Despite a total molybdenum thickness lower by 45 nm with respect to the reference module, the modules exhibit performances which are equivalent.

FIG. 8 illustrates the results of selenization tests on different electrode coatings. The thickness of the electrode coating on which the electrode coating has been selenized is represented on the ordinates. For these tests, the electrode coatings were annealed at 520° C. under an atmosphere comprising selenium. The following samples were analysed:

### Example 11

### MoON 05

glass (3mm)/Si₃N₄ (140 nm)/Mo (200 nm)/MoON (5 nm)/Mo (30 nm),

### Example 12

### MoON 15

glass (3mm)/Si₃N₄ (140 nm)/Mo (200 nm)/MoON (15 nm)/Mo (30 nm),

### Example 13

### MoON 30

glass (3mm)/Si₃N₄ (140 nm)/Mo (200 nm)/MoON (30 nm)/Mo (30 nm),

### Example 14

### TiON 05

glass (3mm)/Si₃N₄ (140 nm)/Mo (200 nm)/TiON (5 nm)/Mo (30 nm),

### Example 15

### TiON 15

glass (3mm)/Si₃N₄ (140 nm)/Mo (200 nm)/TiON (15 nm)/Mo (30 nm),

### Example 16

### TiON 30

glass (3mm)/Si₃N₄ (140 nm)/Mo (200 nm)/TiON (30 nm)/Mo (30 nm),

### Example 17

### V1209

glass (3mm)/Si₃N₄ (140 nm)/Mo (425 nm)

As illustrated in FIG. 8, a barrier layer to selenization, even of 5 nm, whether the material is TiON or MoON, has a protective effect against the selenization of the main molybdenum-based layer 8. In all the examples, the molybdenum-based upper layer 12 was completely transformed into MoSe₂.

1. A conducting substrate, comprising:
a carrier substrate; and
an electrode coating formed on the carrier substrate,
wherein the electrode coating comprises:
a main molybdenum-comprising layer formed on the carrier substrate;
a selenization barrier layer formed on the main molybdenum-comprising layer, the selenization barrier layer having a thickness of less than or equal to 50 nm; and
an upper layer comprising a metal M capable of forming, after sulfurization and/or selenization, an ohmic contact layer with a photoactive semiconducting material formed on the selenization barrier layer.

2. The conducting substrate of claim 1, wherein the selenization barrier layer comprises a metal nitride or oxynitride of titanium, molybdenum, zirconium, or tantalum, wherein an oxygen content, x, of the metal nitride or oxynitride satisfies the relation x=O/(O+N) with x=0 or 0<x<1.

3. The conducting substrate of claim 2, wherein the selenization barrier layer comprises a metal oxynitride of titanium, molybdenum, zirconium, or tantalum and the metal oxynitride has an oxygen content x=O/(O+N) with 0<x<1.

4. The conducting substrate of claim 1, wherein the selenization barrier layer molybdenum-comprising compound with a high content of oxygen and/or nitrogen.

5. The conducting substrate of claim 4, wherein the selenization barrier layer has a resistivity of between 20 μohm.cm and 50 μohm.cm.

6. The conducting substrate of claim 1, wherein the metal M is capable of forming a compound of a semiconducting sulfide and/or selenide type of p type with a concentration of charge carriers of greater than or equal to 10¹⁶/cm³ and a work function of greater than or equal to 4.5 eV.

7. The conducting substrate of claim 6, wherein the upper layer comprising the metal M is a molybdenum-comprising and/or tungsten-comprising layer.

8. A semiconducting device, comprising:
a carrier substrate; and
an electrode coating formed on the carrier substrate,
wherein the electrode coating comprises:
a main molybdenum-comprising layer;
a selenization barrier layer formed on the main molybdenum-comprising layer;
a photoactive layer comprising a photoactive semiconducting material comprising copper and selenium and/or sulfur chalcopyrite, the photoactive layer being formed on the selenization barrier layer; and
between the selenization barrier layer and the photoactive layer, an ohmic contact layer comprising a compound of a sulfide and/or selenide of a metal M.

9. The semiconducting device of claim 8, wherein the ohmic contact layer is a semiconducting material of p type with a concentration of charge carriers of greater than or equal to 10¹⁶/cm³ and a work function of greater than or equal to 4.5 eV.

10. The semiconducting device of claim 9, wherein the ohmic contact layer comprises a compound of molybdenum and/or tungsten sulfide and/or selenide type.

11. A photovoltaic cell comprising:
the semiconducting device of claim 8; and
a transparent electrode coating formed on the photoactive layer of semiconducting device.

12. A process for manufacturing a conducting substrate, the process comprising:
depositing a main molybdenum-comprising layer on a carrier substrate;
depositing a selenization barrier layer on the main molybdenum-comprising layer;
depositing, on the selenization barrier layer, an upper layer comprising a metal M capable of forming, after sulfurization and/or selenization, an ohmic contact layer with a photoactive semiconducting material; and
transforming the upper layer comprising the metal M into a sulfide and/or selenide of the metal M.

13. The process of claim 12, further comprising:
forming a photoactive layer, by selenizing and/or sulfurizing, on the upper layer comprising the metal M, wherein the transformation of the upper layer is carried out before or during the formation of the photoactive layer.

14. The process of claim 12, wherein, after sulfurization and/or selenization, the upper layer is a semiconductor of p type with a concentration of charge carriers of greater than or equal to 10¹⁶/cm³ and a work function of greater than or equal to 4.5 eV.

15. The process of claim 13, wherein the formation of the photoactive layer comprises selenization and/or sulfurization at a temperature of greater than or equal to 300° C.

16. The conducting substrate of claim 1, wherein the selenization barrier layer has a thickness of less than or equal to 30 nm.

17. The conducting substrate of claim 1, wherein the selenization barrier layer has a thickness of less than or equal to 20 nm.

18. The conducting substrate of claim 3, wherein the metal oxynitride has an oxygen content x=O/(O+N) with 0.05<x<0.95.

19. The conducting substrate of claim 3, wherein the metal oxynitride has an oxygen content x=O/(O+N) with 0.1<x<0.9.
